(19) United States
(12) Patent Application Publication
(10) Pub. No.: US 2024/0099156 A1
(43) Pub. Date: Mar. 21, 2024

(54) MAGNETIC MEMORY DEVICE

(71) Applicant: Kioxia Corporation, Tokyo (JP)

(72) Inventors: Kazuya SAWADA, Seoul (KR); Toshihiko NAGASE, Seoul (KR); Kenichi YOSHINO, Seongnam-si Gyeonggi-do (KR); Hyungjun CHO, Seoul (KR); Naoki AKIYAMA, Seoul (KR); Takuya SHIMANO, Seoul (KR); Tadaaki OIKAWA, Seoul (KR)

(73) Assignee: Kioxia Corporation, Tokyo (JP)

(21) Appl. No.: 18/466,868

(22) Filed: Sep. 14, 2023

(30) Foreign Application Priority Data
Sep. 16, 2022 (JP) 2022-148039

(51) Int. Cl. H10N 50/80; H10B 61/00; H10N 50/01; H10N 50/20

(52) U.S. Cl. CPC H10N 50/80; H10B 61/10; H10N 50/01; H10N 50/20

(57) ABSTRACT

According to one embodiment, a magnetic memory device includes an electrode, and a magnetoresistance effect element provided on the electrode. The electrode includes a first electrode portion and a second electrode portion provided between the magnetoresistance effect element and the first electrode portion and containing a metal element selected from molybdenum (Mo) and ruthenium (Ru).

### CROSS-REFERENCE TO RELATED APPLICATIONS

This application is based upon and claims the benefit of priority from Japanese Patent Application No. 2022-148039, filed Sep. 16, 2022, the entire contents of which are incorporated herein by reference.

### FIELD

Embodiments described herein relate generally to a magnetic memory device.

### BACKGROUND

A magnetic memory device has been proposed in which magnetoresistance effect elements are integrated on a semiconductor substrate.

### BRIEF DESCRIPTION OF THE DRAWINGS

FIG. 1 is a cross-sectional view schematically showing a configuration of a magnetic memory device according to an embodiment.

FIG. 2 is a cross-sectional view schematically showing a configuration of a magnetoresistance effect element contained in the magnetic memory device according to the embodiment.

FIG. 3 is a cross-sectional view schematically illustrating a part of a method of manufacturing the magnetic memory device according to the embodiment.

FIG. 4 is a cross-sectional view schematically illustrating a part of a method of manufacturing the magnetic memory device according to the embodiment.

FIG. 5 is a perspective view schematically showing a brief configuration of an applied example of the magnetic memory device according to the embodiment.

### DETAILED DESCRIPTION

In general, according to one embodiment, a magnetic memory device includes: an electrode; and a magnetoresistance effect element provided on the electrode, wherein the electrode includes a first electrode portion and a second electrode portion provided between the magnetoresistance effect element and the first electrode portion and containing a metal element selected from molybdenum (Mo) and ruthenium (Ru).

Embodiments will be described hereinafter with reference to the accompanying drawings.

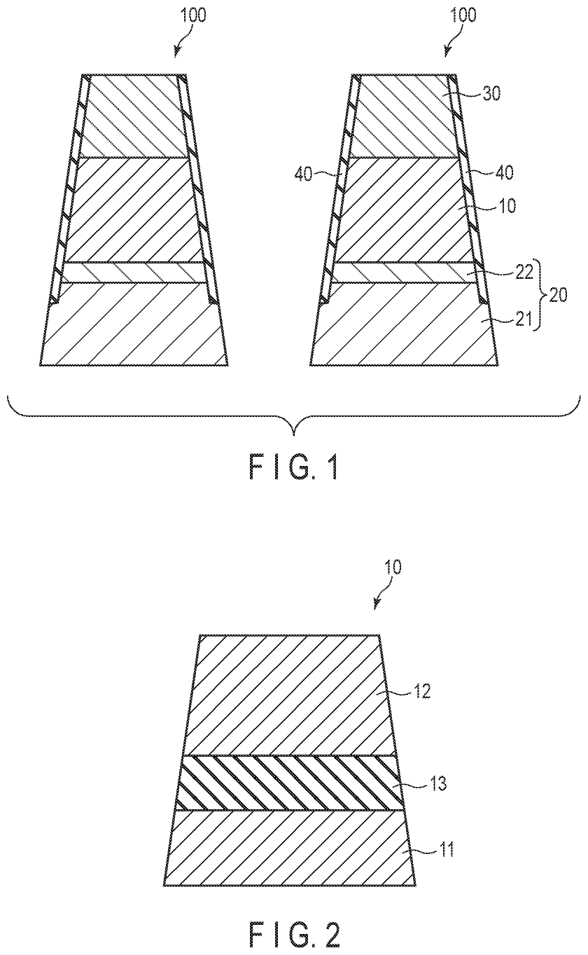

FIG. 1 is a cross-sectional view schematically showing a configuration of a magnetic memory device according to the embodiment.

The magnetic memory device of this embodiment has a configuration in which a plurality of stacked structures 100 are provided on a lower structure (not shown) that includes a semiconductor substrate.

The stacked structures 100 each include a magnetoresistance effect element 10, an electrode 20, a hard mask 30, and a sidewall insulating layer 40.

FIG. 2 shows a schematic cross-sectional view of the magnetoresistance effect element 10.

The magnetoresistance effect element 10 is a magnetic tunnel junction (MTJ) device and is provided on the electrode 20. The magnetoresistance effect element 10 has a stacked structure including a storage layer (first magnetic layer) 11, a reference layer (second magnetic layer) 12 and a tunnel barrier layer (nonmagnetic layer) 13.

The storage layer 11 is a ferromagnetic layer having a variable magnetization direction and includes, for example, a CoFeB layer containing cobalt (Co), iron (Fe) and boron (B). The term “variable magnetization direction” means that the magnetization direction changes for a given write current.

The reference layer 12 is a ferromagnetic layer having a fixed magnetization direction and includes, for example, a CoFeB layer containing cobalt (Co), iron (Fe) and boron (B). The term “fixed magnetization direction” means that the magnetization direction does not change for a given write current.

The tunnel barrier layer 13 is an insulating layer provided between the storage layer 11 and the reference layer 12, and includes, for example, an MgO layer containing magnesium (Mg) and oxygen (O).

When the magnetization direction of the storage layer 11 is parallel to the magnetization direction of the reference layer 12, the magnetoresistance effect element 10 exhibits a low resistance state. When the magnetization direction of the storage layer 11 is antiparallel to the magnetization direction of the reference layer 12, the magnetoresistance effect element 10 exhibits a high resistance state. Therefore, the magnetoresistance effect element 10 can store binary data according to its resistance state (low resistance state and high resistance state).

The magnetoresistance effect element 10 is constituted by a spin transfer torque (STT) type magnetoresistance effect element and has perpendicular magnetization. That is, the magnetization direction of the storage layer 11 is perpendicular to its main surface, and the magnetization direction of the reference layer 12 is perpendicular to its main surface.

Note that FIG. 2 shows a bottom-free type magnetoresistance effect element in which the storage layer 11 is located on a lower layer side of the reference layer 12, but a top-free type magnetoresistance effect element in which the storage layer 11 is located on an upper layer side of the reference layer 12 may be used.

Let us now return to the explanation of FIG. 1. The electrode 20 functions as a bottom electrode of the magnetoresistance effect element 10 and includes a first electrode portion 21 and a second electrode portion 22.

The first electrode portion 21 contains carbon (C). Specifically, the first electrode portion 21 contains carbon as a major component and is formed from a carbon layer that contains substantially no elements other than carbon.

The second electrode portion 22 is provided between the magnetoresistance effect element 10 and the first electrode portion 21 and contains a metal element selected from molybdenum (Mo) and ruthenium (Ru). Specifically, the second electrode portion 22 is formed from a molybdenum layer or ruthenium layer that contains a metal element selected from molybdenum and ruthenium as a main component and substantially contains no elements other than molybdenum and ruthenium. The upper surface of the second electrode portion 22 is in contact with the lower surface of the magnetoresistance effect element 10, and the lower surface of the second electrode portion 22 is in contact with the upper surface of the first electrode portion 21.

The hard mask 30 is provided on the magnetoresistance effect element 10 and is formed of a conductive material. The hard mask 30 functions as a mask used to form the pattern of the magnetoresistance effect element 10 and the pattern of the electrode 20. The hard mask 30 functions as the top electrode of the magnetoresistance effect element 10 as well.

The sidewall insulating layer 40 is provided along a side surface of the magnetoresistance effect element 10, a side surface of the second electrode portion 22, and an upper portion of a side surface of the first electrode portion 21. The sidewall insulating layer 40 has the function of protecting the magnetoresistance effect element 10.

Next, with reference to FIGS. 3, 4 and 1, a method of manufacturing the magnetic memory device according to the embodiment will be described.

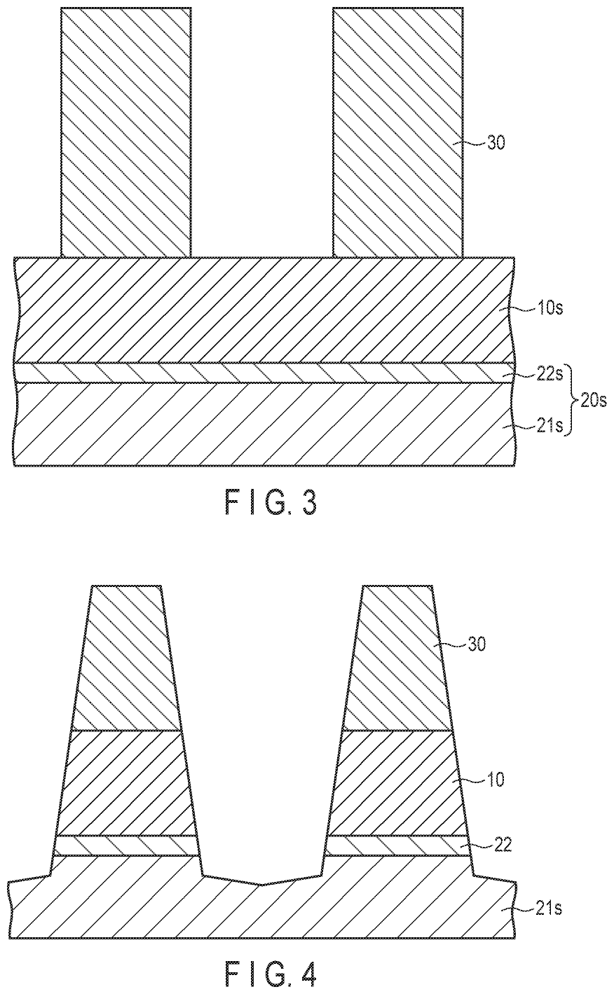

First, as shown in FIG. 3, an electrode layer 20s including a first electrode layer 21s and a second electrode layer 22s located on the first electrode layer 21s is formed on a lower structure (not shown) including a semiconductor substrate. The first electrode layer 21s is formed from a carbon layer and the second electrode layer 22s is formed from a molybdenum layer or a ruthenium layer. Subsequently, a magnetoresistance effect element layer 10s including a storage layer, a reference layer, and a tunnel barrier layer is formed on an electrode layer 20s. Further, a hard mask 30 is formed on the magnetoresistance effect element layer 10s.

Next, as shown in FIG. 4, the magnetoresistance effect element layer 10s and the second electrode layer 22s are etched using the hard mask 30 as a mask. More specifically, the etching is performed by ion beam etching (IBE). In this etching process, the upper portion of the first electrode layer 21s is etched as well. Here, a portion of the hard mask 30 is etched as well. With this etching process, the pattern of the magnetoresistance effect element 10 and the pattern of the second electrode portion 22 can be obtained.

Next, as shown in FIG. 1, the sidewall insulating layer 40 is formed on a side surface of the pattern obtained in the etching process of FIG. 4. Subsequently, the first electrode layer 21s is etched using the hard mask 30 as a mask to form the first electrode portion 21. More specifically, the etching is performed by reactive ion etching (RIE). At this time, the magnetoresistance effect element 10 is protected by the sidewall insulating layer 40.

In this manner, the magnetic memory device shown in FIG. 1 is formed.

As described above, in this embodiment, the electrode 20 includes a second electrode portion 22 provided between the magnetoresistance effect element 10 and the first electrode portion 21, and the second electrode portion 22 contains a metal element selected from molybdenum and ruthenium. With this configuration, according to this embodiment, proper patterning as described below can be carried out.

In the case where the second electrode portion 22 is not provided, the material component of the magnetoresistance effect element layer 10s generated in the IBE process of FIG. 4 may undesirably remain on the surface of the first electrode layer 21s by knocking. That is, the material component of the magnetoresistance effect element layer 10s may undesirably remain on the surface of the first electrode layer 21s as residue. Therefore, when etching the first electrode layer 21s in the RIE process after the process shown in FIG. 4, the etching of the first electrode layer 21s may be inhibited by the residue remaining on the surface of the first electrode layer 21s. As a result, a portion of the first electrode layer 21s may remain between adjacent stacked structures 100, and the first electrode layer 21s may not be sufficiently separated between adjacent stacked structures 100. In particular, as the magnetic memory device is miniaturized and the distance between adjacent stacked structures 100 becomes smaller, there rises an increasing possibility that the first electrode layer 21s cannot be sufficiently separated.

In this embodiment, a second electrode layer 22s containing a metal element selected from molybdenum and ruthenium is provided between the magnetoresistance effect element layer 10s and the first electrode layer 21s. Molybdenum and ruthenium are less likely to remain on the surface of the first electrode layer 21s due to knocking. Further, in the IBE process shown in FIG. 4, since the second electrode layer 22s is etched after the magnetoresistance effect element layer 10s is etched, the material components of the magnetoresistance effect element layer 10s generated by IBE are removed when the second electrode layer 22 is etched. Therefore, there is no substantial residue remaining on the surface of the first electrode layer 21s that would inhibit RIE. In this manner, the first electrode layer 21s can be etched reliably in the RIE process, and the first electrode layer 21s can be reliably separated between adjacent stacked structures 100.

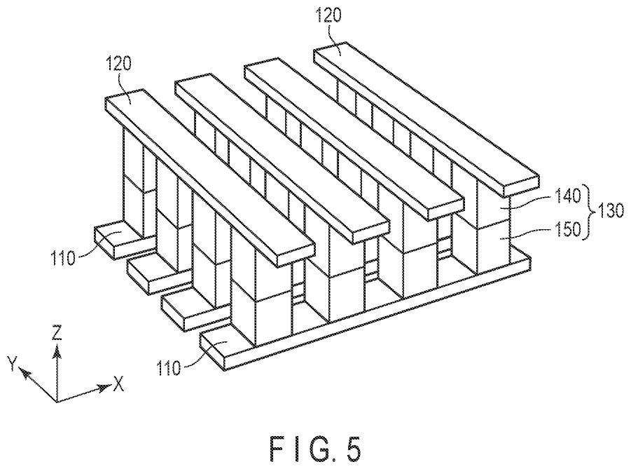

FIG. 5 is a perspective view schematically showing a brief structure of a magnetic memory device to which the stacked structure 100 described above is applied. Note here that X, Y, and Z directions shown in FIG. 5 are intersect each other, and more specifically, the X, Y, and Z directions are orthogonal to each other.

The magnetic memory device shown in FIG. 5 includes a plurality of first wiring lines 110 each extending in the X direction, a plurality of second wiring lines 120 each extending in the Y direction, and a plurality of memory cells 130 each provided between each respective one of the plurality of first wiring lines 110 and each respective one of the plurality of second wiring lines 120. The first wiring lines 110 correspond to word lines, whereas the second wiring lines 120 correspond to bit lines, or vice versa.

The memory cells 130 each includes a magnetoresistance effect element 140 and a selector (switching element) 150 connected in series to the magnetoresistance effect element 140, and the magnetoresistance effect element 140 and the selector 150 are provided between the respective first wiring line 110 and the respective second wiring line 120. The memory cell 130 includes the stacked structure 100 described above, and in FIG. 5, the magnetoresistance effect element 140 substantially corresponds to the stacked structure 100 described above.

The selector 150 is a 2-terminal type switching device including a bottom electrode, a top electrode, and a selector material layer provided between the bottom electrode and the top electrode, and has characteristics in which it changes from an off state to an on state when the voltage applied between the two terminals reaches or exceeds a threshold voltage.

That is, by applying a voltage between a first wiring line 110 and a second wiring line 120 to set the respective selector 150 to the on state, a current flows to the magnetoresistance effect element 140, thus making it possible to write to or read from the magnetoresistance effect element 140.

Note that as a material for the selector 150, for example, a material having such properties (snap-back properties) that the resistance value drops sharply at a predetermined voltage and the applied voltage drops sharply therewith and the current increases can as well be applied.

Further, the electrode 20 shown in FIG. 1 may as well be used as the bottom electrode of the magnetoresistance effect element 140 and the top electrode of the selector 150.

By applying the above-described stacked structure 100 to a magnetic memory device as shown in FIG. 5, an excellent magnetic memory device can be obtained.

Note that in FIG. 5, the magnetoresistance effect element 140 is provided on the upper layer side of the selector, but the magnetoresistance effect element 140 may as well be provided on the lower layer side of the selector.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A magnetic memory device comprising:
an electrode; and
a magnetoresistance effect element provided on the electrode,
wherein
the electrode includes a first electrode portion and a second electrode portion provided between the magnetoresistance effect element and the first electrode portion and containing a metal element selected from molybdenum (Mo) and ruthenium (Ru).

2. The device of claim 1, wherein
the first electrode portion contains carbon (C).

3. The device of claim 1, further comprising:
a hard mask provided on the magnetoresistance effect element.

4. The device of claim 1, further comprising:
a sidewall insulating layer provided along a side surface of the magnetoresistance effect element and a side surface of the second electrode portion.

5. The device of claim 1, wherein
the magnetoresistance effect element includes a first magnetic layer having a variable magnetization direction, a second magnetic layer having a fixed magnetization direction, and a nonmagnetic layer provided between the first magnetic layer and the second magnetic layer.

6. The device of claim 1, further comprising:
a switching element connected in series to the magnetoresistance effect element.

7. The device of claim 6, further comprising:
a first wiring line extending in a first direction; and
a second wiring line extending in a second direction intersecting the first direction,
wherein
the magnetoresistance effect element and the switching element are provided between the first wiring line and the second wiring line.

8. A method of manufacturing a magnetic memory device, comprising:
forming an electrode layer including a first electrode layer and a second electrode layer on the first electrode layer;
forming a magnetoresistance effect element layer on the electrode layer;
forming a hard mask on the magnetoresistance effect element layer;
etching the magnetoresistance effect element layer and the second electrode layer using the hard mask as a mask,
wherein
the second electrode layer contains a metal element selected from molybdenum (Mo) and ruthenium (Ru).

9. The method of claim 8, wherein
the first electrode layer contains carbon (C).

10. The method of claim 8, wherein
etching the magnetoresistance effect element layer and the second electrode layer is performed by ion beam etching (IBE).

11. The method of claim 8, further comprising:
forming a sidewall insulating layer on a side surface of a pattern obtained by etching the magnetoresistance effect element layer and the second electrode layer; and
etching the first electrode layer using the hard mask as a mask after forming the sidewall insulating layer.

12. The method of claim 11, wherein
etching the first electrode layer is performed by reactive ion etching (RIE).
